(19) United States
(12) Patent Application Publication
(10) Pub. No.: US 2026/0334203 A1
(43) Pub. Date: Oct. 22, 2026

(54) SEMICONDUCTOR DEVICE COMPISING A GATE INTERCONNECTION LINE

(71) Applicant: Infineon Technologies AG, Neubiberg (DE)

(72) Inventors: Thomas Ralf SIEMIENIEC, Villach (AT); Andreas KORZENIETZ, Putzbrunn (DE); Dethard PETERS, Höchstadt (DE)

(21) Appl. No.: 19/648,431

(22) Filed: Apr. 15, 2026

(30) Foreign Application Priority Data
Apr. 16, 2025 (DE) 102025114889.9

(51) Int. Cl. H10W 20/42; H10D 62/10; H10D 62/832; H10W 20/00

(52) U.S. Cl. CPC H10W 20/422; H10D 62/107; H10D 62/127; H10D 62/8325; H10W 20/0698

(57) ABSTRACT

A semiconductor device is proposed. The semiconductor device includes a SiC semiconductor body. The SiC semiconductor body includes a transistor cell array at a first side of the SiC semiconductor body. The semiconductor device further includes a gate interconnection line. At least a portion of the gate interconnection line is arranged between an edge of the SiC semiconductor body and the transistor cell array. The semiconductor device further includes an intermediate dielectric arranged between the gate interconnection line and the SiC semiconductor body. The semiconductor device further includes a p-doped well region. The semiconductor device further includes an n-doped interconnection region arranged between the gate interconnection line and the p-doped well region. The n-doped interconnection region and the p-doped well region are electrically connected together by a first contact arranged at the first side between the gate interconnection line and the edge of the SiC semiconductor body. The n-doped interconnection region and the p-doped well region are further electrically connected together by a second contact at the first side. The gate interconnection line is arranged between the first contact and the second contact.

### RELATED APPLICATION

This application claims priority to German Patent Application No. 102025114889.9, filed on Apr. 16, 2025, entitled “SEMICONDUCTOR DEVICE COMPRISING A GATE INTERCONNECTION LINE”, which is incorporated by reference herein in its entirety.

### TECHNICAL FIELD

The present disclosure relates to a semiconductor device and a method for manufacturing such a device, particularly involving silicon carbide (SiC) semiconductor technology. Specifically, the disclosure pertains to the arrangement and interconnection of transistor cell arrays, gate interconnection lines, and doped regions within a SiC semiconductor body to optimize electrical performance and integration.

### BACKGROUND

Technology development of new generations of semiconductor devices, e.g. insulated gate field effect transistors (IGFETs) such as metal oxide semiconductor field effect transistors (MOSFETs) or insulated gate bipolar transistors (IGBTs) or junction field effect transistors (JFETs), aims at increasing device functionalities per chip area while meeting with specified quality and reliability requirements.

In the field of semiconductor devices, particularly those utilizing silicon carbide (SiC) technology, it is common to employ transistor cell arrays for various applications, including power electronics. Such devices typically involve the integration of multiple doped regions within a SiC semiconductor body to facilitate electrical connections and enhance device performance. Gate interconnection lines and dielectric layers are often incorporated to manage electrical signals and isolate different regions within the semiconductor device, e.g. in an edge termination area surrounding the transistor cell area. The arrangement and properties of these components are crucial for achieving desired electrical characteristics, such as avalanche robustness.

Despite the substantial advances in SiC semiconductor technology, challenges remain in optimizing the electrical connectivity and minimizing resistance between doped regions without adversely increasing the required chip area. Additionally, the geometric configuration of contacts and interconnection lines can impact the overall performance and reliability of the device. The need to balance the thickness and width of various components, such as contacts and dielectric layers, further complicates the design process.

It is therefore a technical problem to provide a semiconductor device that at least partially meets the above challenges.

### SUMMARY

An example of the present disclosure relates to a semiconductor device. The semiconductor device includes a SiC semiconductor body. The SiC semiconductor body includes a transistor cell array at a first side of the SiC semiconductor body. The semiconductor device further includes a gate interconnection line. At least a portion of the gate interconnection line is arranged between an edge of the SiC semiconductor body and the transistor cell array. The semiconductor device further includes an intermediate dielectric arranged between the gate interconnection line and the SiC semiconductor body. The semiconductor device further includes a p-doped well region. The semiconductor device further includes an n-doped interconnection region arranged between the gate interconnection line and the p-doped well region. The n-doped interconnection region and the p-doped well region are electrically connected together by a first contact arranged at the first side between the gate interconnection line and the edge of the SiC semiconductor body. The n-doped interconnection region and the p-doped well region are further electrically connected together by a second contact at the first side. The gate interconnection line is arranged between the first contact and the second contact.

Another example of the present disclosure relates to a further method of manufacturing a semiconductor device. The method includes forming a transistor cell array at a first side of a SiC semiconductor body. The method further includes forming an intermediate dielectric on the SiC semiconductor body. The method further includes forming a gate interconnection line on the intermediate dielectric. At least a portion of the gate interconnection line is formed between an edge of the SiC semiconductor body and the transistor cell array. The method further includes forming a p-doped well region. The method further includes forming an n-doped interconnection region arranged between the gate interconnection line and the p-doped well region. The n-doped interconnection region and the p-doped well region are electrically connected together by a first contact arranged at the first side between the gate interconnection line and the edge of the SiC semiconductor body. The n-doped interconnection line and the p-doped well region are further electrically connected together by a second contact at the first side. The gate interconnection line is arranged between the first contact and the second contact.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate embodiments of semiconductor devices and together with the description serve to explain principles of the embodiments. Further embodiments are described in the following detailed description and the claims.

FIG. 1 schematically and exemplarily illustrates a cross-sectional view of a semiconductor device including a portion of a gate interconnection line that is arranged between an edge of a SiC semiconductor body and a transistor cell array.

FIG. 2 is an exemplary and more detailed illustration of the cross-sectional view of FIG. 1.

FIG. 3A is a top view illustrating a corner portion of a transistor cell array and surrounding gate interconnection line according to a configuration example of a semiconductor device.

FIG. 3B is an exemplary illustration of a cross-sectional view along line B-B′ of FIG. 3A.

FIG. 3C is an exemplary illustration of a cross-sectional view along line C-C′ of FIG. 3A.

FIG. 3D is a more detailed illustration of the top view of FIG. 3A in the area of the lines B-B′ and A-A′.

### DETAILED DESCRIPTION

In the following detailed description, reference is made to the accompanying drawings, which form a part hereof and in which are shown by way of illustrations specific examples in which semiconductor substrates may be processed. It is to be understood that other examples may be utilized and structural or logical changes may be made without departing from the scope of the present disclosure. For example, features illustrated or described for one example can be used on or in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state.

If two elements A and B are combined using an “or”, this is to be understood to disclose all possible combinations, i.e. only A, only B as well as A and B, if not explicitly or implicitly defined otherwise. An alternative wording for the same combinations is “at least one of A and B” or “A and/or B”. The same applies, mutatis mutandis, for combinations of more than two elements.

Ranges given for physical dimensions include the boundary values. For example, a range for a parameter y from a to b reads as a≤y≤b. The same holds for ranges with one boundary value like “at most” and “at least”.

Main constituents of a layer or a structure from a chemical compound or alloy are such elements which atoms form the chemical compound or alloy. For example, silicon (Si) and carbon (C) are the main constituents of a silicon carbide (SiC) layer.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

A configuration example of a semiconductor device includes a transistor cell array at a first side of a SiC semiconductor body. The semiconductor device further includes a gate interconnection line. At least a portion of the gate interconnection line is arranged between an edge of the SiC semiconductor body and the transistor cell array. The semiconductor device further includes an intermediate dielectric arranged between the gate interconnection line and the SiC semiconductor body. The semiconductor device further includes a p-doped well region. The semiconductor device further includes an n-doped interconnection region arranged between the gate interconnection line and the p-doped well region. The n-doped interconnection region and the p-doped well region are electrically connected together by a first contact arranged at the first side between the gate interconnection line and the edge of the SiC semiconductor body. The n-doped interconnection region and the p-doped well region are further electrically connected together by a second contact at the first side. The gate interconnection line is arranged between the first contact and the second contact.

The semiconductor device may be part of an integrated circuit or may be a discrete semiconductor device or a semiconductor module, for example. The semiconductor device may be or may include an insulated gate field effect transistor (IGFET) such as a metal oxide semiconductor field effect transistor (MOSFET), or an insulated gate bipolar transistor (IGBT), or a junction field effect transistor (JFET), for example. The semiconductor device may be a vertical semiconductor device having a load current flow between a first side and a second side opposite to the first surface. The vertical power semiconductor device may be configured to conduct currents of more than 1A, or more than 10 A, or more than 30 A, or more than 50 A, or more than 75 A, or even more than 100 A, and may be further configured to block voltages between load electrodes, e.g. between collector and emitter of an IGBT, or between drain and source of a MOSFET or JFET, in the range of several hundreds of up to several thousands of volts, e.g. 300V, 400 V, 650 V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The semiconductor device may be based on a SiC semiconductor substrate from a crystalline SiC material. The crystalline SiC material may have a hexagonal crystal lattice, by way of example. For example, the semiconductor material may be 2H—SiC (SiC of the 2H polytype), 6H—SiC or 15R—SiC. According to an example, the semiconductor material is silicon carbide of the 4H polytype (4H—SiC). The SiC semiconductor body may include or consist of a SiC semiconductor base substrate having one or more than one semiconductor layer, e.g. epitaxially grown layers, thereon. The semiconductor layer(s) may be formed as part of a multi-epitaxial approach for forming a super junction structure, SJ structure, and/or for forming a current spread layer, and/or for forming a device layer for including doped regions such as source and body regions therein, for example. During the multi-epitaxial approach for forming the SJ structure a masked p-implant and/or n-implant may be used between successive epi growths.

The first side may be a front side or a top side of the SiC semiconductor body, and the SiC semiconductor body may further have a second side that may be a back side or a rear side of the SiC semiconductor body, for example. The SiC semiconductor body may be attached to a lead frame via the second side, for example. Over the first side of the SiC semiconductor body, bond pads may be arranged, and bond wires may be bonded on the bond pads, for example.

For realizing a desired current carrying capacity, the semiconductor device may be designed by a plurality of parallel-connected semiconductor device cells. The parallel-connected semiconductor device cells may, for example, be semiconductor device cells formed in the shape of a stripe or a stripe segment. Of course, the semiconductor device cells can also have any other shape, e.g. circular, elliptical, polygonal such as hexagonal or octahedral. The semiconductor device cells may be arranged in the transistor cell array of the SiC semiconductor body. The transistor cell array may be an area where an emitter region of an IGBT (or a source region of a MOSFET or JFET) and a collector region of an IGBT (or a drain region of a MOSFET or JFET) are arranged opposite to one another along the vertical direction. In the transistor cell array, a load current may enter or exit the SiC semiconductor body of the semiconductor device, e.g. via contact plugs at the first side of the SiC semiconductor body. The semiconductor device may further include an edge termination area that may include a termination structure. In a blocking mode or in a reverse biased mode of the semiconductor device, the blocking voltage between the transistor cell array and a field-free region laterally drops across the termination structure. The termination structure may have a higher or a slightly lower voltage blocking capability than the transistor cell array. The termination structure may include a junction termination extension (JTE) with or without a variation of lateral doping (VLD), one or more laterally separated guard rings, or any combination thereof, for example.

The gate interconnection line may be arranged outside of the active transistor cell array, e.g. in the rim area of the chip. The gate interconnection line (also called gate runner) may partly or fully surround the transistor cell array. For example, the gate interconnection line may be formed close to one, two, e.g. opposite two, three or four edges of the SiC semiconductor body or die. The gate interconnection line may include one or more conductive material(s), e.g. metal, metal alloys, e.g. Cu, Au, AlCu, AlSiCu, Ti, W, TiW, Mo, Au, NiP, Ta, Ag, or alloys thereof, metal compounds, e.g. TiN. The one or more conductive materials may form a layer stack, for example. The gate interconnection line may electrically connect the gate electrode in the transistor cell array to a gate pad, for example. For example, the gate interconnection line may merge or turn into the gate pad over the first side of the SiC semiconductor body, for example.

The intermediate dielectric may be arranged between the gate interconnection line and a surface of the SiC semiconductor body at the first side, for example. A top side of the intermediate dielectric may directly adjoin a bottom side of the gate interconnection line, for example. A bottom side of the intermediate dielectric may directly adjoin to a surface of the SiC semiconductor body at the first side. The intermediate dielectric may include one or more dielectric material(s), e.g. oxides such as SiO₂, nitrides such as Si₃N₄, high-k dielectrics such as Al₂O₃, ZrO₂, HfO₂, AlN, alumisilicate AlSiOₓ, silicon doped HfO₂, lanthanum doped HfO₂, TiO₂, Y₂O₃ or Si₃N₄, ONO (oxide-nitride-oxide), or any stacked combination thereof. Oxides may be thermal oxides and/or deposited and annealed oxides, for example. The intermediate dielectric may laterally extend into the edge termination area and/or be partly arranged on a surface of the SiC semiconductor body at the first side in the transistor cell array.

The first contact may include one or more conductive material(s), e.g. metal, metal alloys, metal compounds, metal silicides, or any combination thereof. The one or more conductive materials may form a layer stack, for example. For example, the first contact may include a silicide layer or a silicide layer stack, e.g. silicides of Ni, or of NiAl, or of Ti, or any combination thereof. An optional barrier, e.g. diffusion barrier layer or barrier layer stack may be formed on the silicide layer or silicide layer stack, e.g. a barrier layer including Ti, TiN, Ti/TiN, Mo or any combination thereof. An optional liner may be formed on the silicide layer or silicide layer stack or on the barrier layer or barrier layer stack. The liner layer or liner layer stack may include W, Mo, or any combination thereof, for example. The first contact may provide an ohmic connection between the p-doped well region and the n-doped interconnection region.

The second contact may include materials or material combinations as described above with respect to the gate interconnection line and/or the first contact. For example, a layer composition of the second contact may correspond to the layer composition of the first contact, and, in addition, the layer composition of the gate interconnection line on top of the layer composition of the first contact.

For example, the p-doped well region may be formed by one, two, three, four or even more overlapping profiles of electrically activated dopants introduced by a plurality of ion implantations at different ion implantation energies, for example.

Examples described herein may allow for chip area savings, in particular in a passive region between the transistor cell array and the edge of the SiC semiconductor substrate or chip/die. Chip area savings can be achieved by omitting chip-area intensive source or emitter interconnection lines for providing a low-ohmic connection from the termination structures to the source or emitter electrode. The low ohmic connection is provided via the n-doped interconnection region ensuring a lower resistance pathway compared to the p-doped well region and supported by the first and second contacts at the first side of the SiC semiconductor body.

For example, a sheet resistance of the n-doped interconnection region may be 20% or less than the sheet resistance of the p-doped well region. This feature brings a significant improvement in the electrical performance of the semiconductor device by ensuring a lower resistance pathway within the n-doped interconnection region compared to the p-doped well region for electrically connecting the second contact, e.g. source contact, to an end portion of the p-doped well region adjoining the termination structure including, for example, p-doped region(s) of the termination structure. Thereby, a low-ohmic connection of the termination structure in the edge termination area to the source or emitter electrode, e.g. second contact, may be achieved without the chip area consumption required when placing a source or emitter interconnection line between the edge of the semiconductor body and the transistor cell array.

For example, the sheet resistance of the n-doped interconnection region may be in a range from 300 Ohm/square to 900 Ohm/square. By providing the n-doped interconnection region, the sheet resistance for interconnecting the termination structure in the edge termination region to the source or emitter contact may be substantially lower than a minimum sheet resistance that may be achieved by an upper limit of p-type doping concentration in the p-doped well region taking into account reasonable depths for the p-type doping concentration and constraints in doping due to the substrate material SiC.

For example, a thickness of the first contact along a vertical direction may be smaller than a thickness of the gate interconnection line. The thickness of the first contact may be in a range from 0.4% to 20% or from 0.4% to 3% of the thickness of the gate interconnection line, for example.

For example, a width of the first contact may be in a range from 4% to 30%, or from 5% to 10% of a width of the gate interconnection line. Exemplary values of the width of the first contact may range from 0.4 μm to 3 μm, or from 0.5 μm to 2 μm. For example, minimum lateral dimensions, e.g. width, may be limited by a minimum contact hole width in the intermediate dielectric.

For example, the thickness of the first contact may be smaller than a thickness of the intermediate dielectric. The thickness of the first contact may be in a range from 10% to 30% of the thickness of the intermediate dielectric, for example. By placing the first contact in a contact opening in the intermediate dielectric, chip area consumption imposed by design rule constraints of minimum widths and distances of a source interconnection lines or source runners formed in a metal layer of a wiring level in the wiring area may be avoided. This allows for reducing chip area consumption.

For example, the p-doped well region may turn into a p-doped edge termination region of an edge termination structure. The p-doped edge termination region may have a higher sheet resistance than the p-doped well region. The p-doped edge termination region may be part of a JTE or VLD termination structure, for example.

For example, a vertical extent of the p-doped edge termination region may be larger than a vertical extent of the n-doped interconnection region. A vertical extent of the p-doped well region may be larger than the vertical extent of the p-doped edge termination region. This may support the managing of electric field distribution and enhancing the device's performance and reliability.

For example, a maximum doping concentration in the p-doped well region may be in a range from 10¹⁸ cm⁻³ to 10¹⁹ cm⁻³. The vertical extent of the p-doped well region may be in a range from 0.5 μm to 1.0 μm or even larger, for example.

For example, a source region in the transistor cell array and the n-doped interconnection region may have a matching vertical concentration profile of n-type dopants. This may simplify manufacturing of the semiconductor device by concurrently forming the source region and the n-doped interconnection region. A single lithographic mask process followed by ion implantation may be used to concurrently form the source region and the n-doped interconnection region, for example.

For example, the transistor cell array may include a plurality of stripe-shaped transistor cells extending in parallel along a first lateral direction. The n-doped interconnection region may include a first sub-region extending in parallel to a first edge of the SiC semiconductor body along the first lateral direction. The n-doped interconnection region may further include a second sub-region extending in parallel to a second edge of the SiC semiconductor body along a second lateral direction. This may contribute to a low-ohmic connection of the termination structure in the edge termination area to the source or emitter electrode by connecting the termination structure in the edge termination area via different edges of the SiC semiconductor body.

For example, a width of the first sub-region along the second lateral direction may be smaller than three times a width of the gate interconnection line over the first sub-region.

For example, a width of the second sub-region may alternate, along the second lateral direction between a first width and a second width. The second width may be smaller than the first width. For example, the alternating width of the second sub-region may be formed by recesses in the second sub-region at one of opposite edges of the second sub-region that is directed toward the transistor cell array, for example.

For example, the second width is in a range from 10% to 30% of the first width. For example, a contact may be arranged in a contact opening formed in the intermediate dielectric over the recesses in the second sub-region. The contact may electrically connect the gate electrode in the transistor cell array and the gate interconnection line, for example.

For example, a trench gate structure segment may be laterally confined, along the second lateral direction, by neighboring segments of the second sub-region having the first width. The trench gate structure segment may be arranged between the transistor cell array and the edge termination array.

For example, the trench gate structure segment may adjoin, along the first lateral direction, a segment of the second sub-region having the second width. For example, a dielectric in the trench gate structure segment, e.g. a gate dielectric, may directly adjoin a lateral end of the second sub-region having the second width.

For example, a gate electrode of the trench gate structure segment may be electrically connected to the gate interconnection line over the trench gate structure segment via a contact opening in the intermediate dielectric.

Details with respect to structure, or function, or technical benefit of features described above with respect to a semiconductor device such as a FET, or JFET, or IGBT likewise apply to the exemplary methods described herein. Processing the SiC semiconductor body may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the disclosure to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Another example of the present disclosure relates to a method of method of manufacturing a semiconductor device. The method includes forming a transistor cell array at a first side of a SiC semiconductor body. The method further includes forming an intermediate dielectric on the SiC semiconductor body. The method further includes forming a gate interconnection line on the intermediate dielectric. At least a portion of the gate interconnection line is formed between an edge of the SiC semiconductor body and the transistor cell array. The method further includes forming a p-doped well region. The method further includes forming an n-doped interconnection region arranged between the gate interconnection line and the p-doped well region. The n-doped interconnection region and the p-doped well region are electrically connected together by a first contact arranged at the first side between the gate interconnection line and the edge of the SiC semiconductor body. The n-doped interconnection line and the p-doped well region are further electrically connected together by a second contact at the first side. The gate interconnection line is arranged between the first contact and the second contact.

For example, the method may further include concurrently forming an n-doped source region in the transistor cell array and the n-doped interconnection region by introducing n-type dopants into the SiC semiconductor body. Concurrently forming an n-doped source region in the transistor cell array and the n-doped interconnection region may include introducing n-type dopants through laterally spaced mask openings by one or more ion implantation processes.

The examples and features described above and below may be combined.

More details and aspects are mentioned in connection with the examples described above or below. Processing a SiC semiconductor wafer or body of the semiconductor devices may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the disclosure to furthering the art. All statements herein reciting principles, aspects, and examples of the disclosure, as well as specific examples thereof, are intended to encompass equivalents thereof.

In the following, further examples of semiconductor devices are explained in connection with the accompanying drawings. Functional and structural details described with respect to the examples above shall likewise apply to the exemplary embodiments illustrated in the figures and described further below.

Details with respect to structure, or function, or technical benefit of features described above likewise apply to the examples below and vice versa.

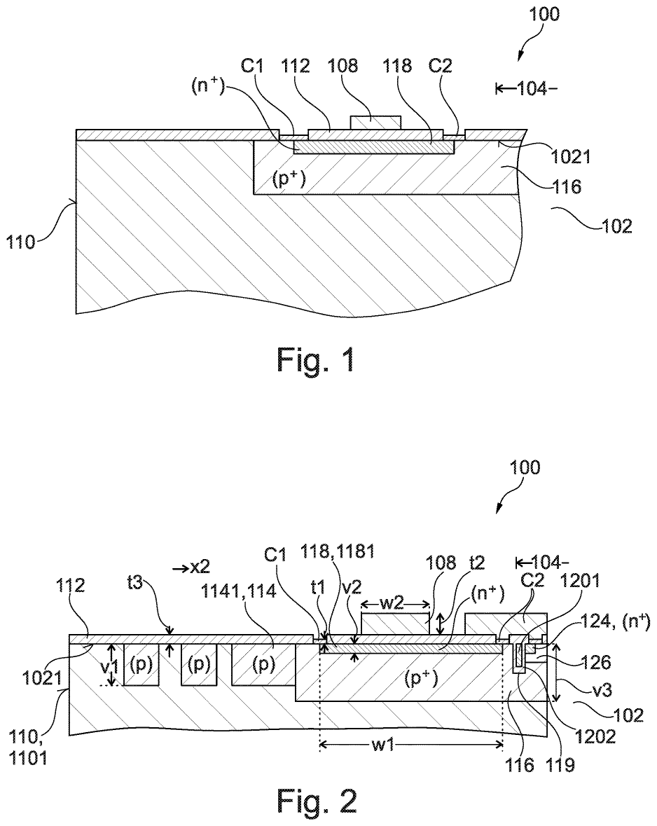

FIG. 1 illustrates a configuration example of a semiconductor device 100 comprising a SiC semiconductor body 102. The SiC semiconductor body 102 includes a transistor cell array 104 (not illustrated in detail) positioned at a first side 1021 of the SiC semiconductor body 102. A gate interconnection line 108 is arranged such that at least a portion of it is located between an edge 110 of the SiC semiconductor body 102 and the transistor cell array 104. An intermediate dielectric 112 is situated between the gate interconnection line 108 and the SiC semiconductor body 102, providing electrical insulation.

The semiconductor device 100 further includes a p-doped well region 116 and an n-doped interconnection region 118. The n-doped interconnection region 118 is positioned between the gate interconnection line 108 and the p-doped well region 116, e.g. embedded in the p-doped well region 116. Electrical connectivity between the n-doped interconnection region 118 and the p-doped well region 116 is established by a first contact C1, which is situated at the first side 1021 between the gate interconnection line 108 and the edge 110 of the SiC semiconductor body 102. Additionally, a second contact C2 at the first side 1021 further connects the n-doped interconnection region 118 and the p-doped well region 116. The gate interconnection line 108 is positioned between the first contact C1 and the second contact C2. The second contact C2 may be part of a first load electrode of the transistor cell area, e.g. a source or emitter electrode being part of a wiring area at first side 1021 of the SiC semiconductor body 102.

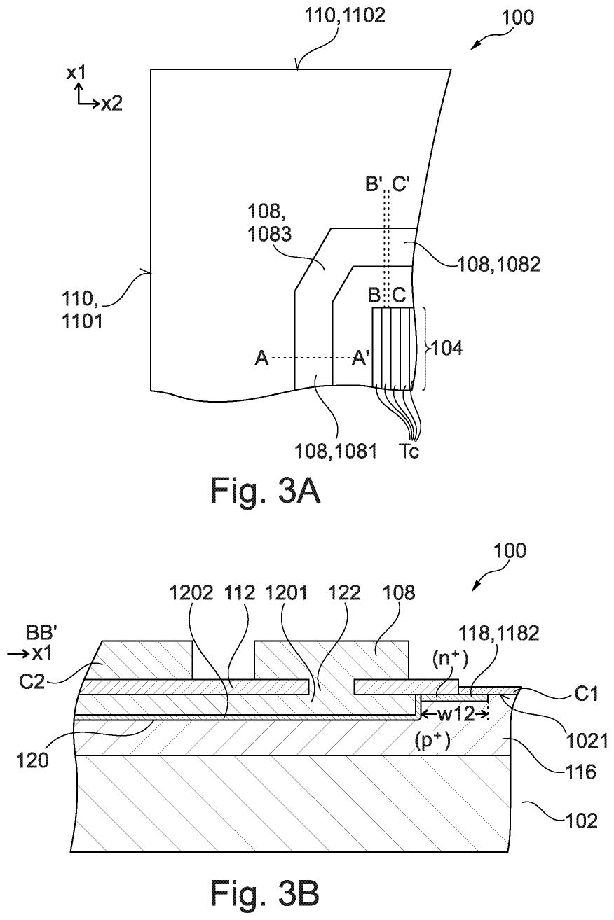

FIG. 2 illustrates a cross-sectional view of a further configuration example of a semiconductor device 100. The exemplary illustration of FIG. 2 provides some more exemplary details than the illustration of FIG. 1.

The n-doped interconnection region 118 is positioned between the gate interconnection line 108 and the p-doped well region 116. One end of the n-doped interconnection region 118 and the p-doped well region 116 are electrically connected by the first contact C1, which is located at the first side 1021 in a contact opening of the intermediate dielectric 112. The other end of the n-doped interconnection region 118 and the p-doped well region 116 are electrically connected by the second contact C2, which is located at the first side 1021. The second contact C2 fills a contact opening of the intermediate dielectric 112 and merges into a load electrode of the transistor cell array 104, e.g. a source or emitter electrode. For example, a layer composition of the second contact C2 may correspond to the layer composition of the first contact as a bottom portion and the layer composition of the gate interconnection line 108 as a top portion on the bottom portion. In other words, the bottom portion of the second contact C2 and the first contact C1 may be concurrently formed, and the top portion of the second contact C2 and the gate interconnection line 108 may be concurrently formed.

A thickness t1 of the first contact C1 along the vertical direction y is smaller than a thickness t2 of the gate interconnection line 108. The thickness t1 of the first contact C1 is also smaller than a thickness t3 of the intermediate dielectric 112.

A width w1 of the first sub-region 1181 along the second lateral direction x2 is smaller than three times a width w2 of the gate interconnection line 108 over the first sub-region 1181.

The p-doped well region 116 transitions into a p-doped edge termination region 1141 of an edge termination structure 114. The p-doped edge termination region 1141 may have a higher sheet resistance than the p-doped well region 116. A vertical extent v1 of the p-doped edge termination region 1141 is larger than a vertical extent v2 of the n-doped interconnection region 118, and a vertical extent v3 of the p-doped well region 116 is larger than the vertical extent v1 of the p-doped edge termination region 1141. In some further examples, the vertical extent v3 of the p-doped well region 116 may be equal to the vertical extent v1 of the p-doped edge termination region 1141.

The transistor cell array 104 includes trench gate structures 119 including a gate electrode 1201 electrically isolated from a surrounding portion of the SiC semiconductor body 102 by a gate dielectric 1202. A channel current enters from an n-doped source region 124 into a channel region of a p-doped body region 126 adjoining a sidewall of the trench gate structures 119 and being controlled in its conductivity by field effect via a voltage applied to the gate electrode 1201.

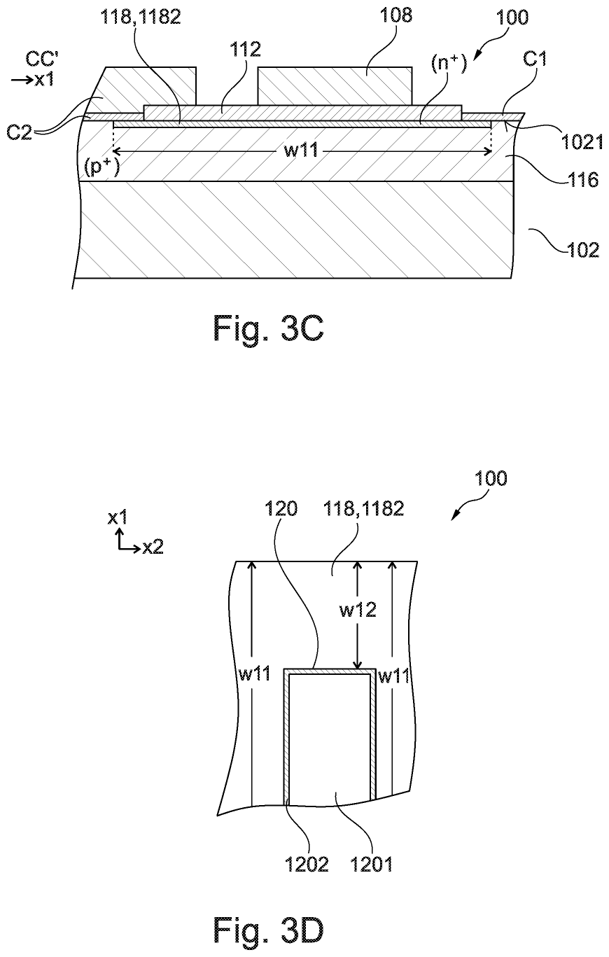

The schematic top view of FIG. 3A illustrates a configuration example of a semiconductor device 100 having a transistor cell array 104 that includes a plurality of stripe-shaped transistor cells TC extending in parallel along the first lateral direction x1. The gate interconnection line 108 includes a first portion 1081 extending in parallel to a first edge 1101 of the SiC semiconductor body 102 along the first lateral direction x1. The first portion 1081 turns, via a corner interconnection portion 1083 of the gate interconnection line 108, into a second portion 1082 of the gate interconnection line 108 that extends in parallel to a second edge 1102 of the SiC semiconductor body 102.

An exemplary cross-sectional view along line A-A′ of FIG. 3A is illustrated in FIG. 2.

FIG. 3B illustrates a cross-sectional view along line B-B′ of FIG. 3A providing a detailed depiction of the structural configuration, highlighting the integration of the gate interconnection line, intermediate dielectric, and doped regions.

The SiC semiconductor body 102 serves as the foundational substrate upon which the device is constructed. The first side 1021 of the semiconductor body is where the transistor cell array is located, although the specific cells are not depicted in FIG. 3B. The gate interconnection line 108 is shown, positioned above the intermediate dielectric 112. The intermediate dielectric 112 acts as an insulating layer, separating the gate interconnection line 108 from the underlying SiC semiconductor body 102.

FIG. 3B also shows the n-doped interconnection region 118, labeled as 1182 having a width w12 in this view, situated between the intermediate dielectric 112 and the p-doped well region 116. The n-doped interconnection region 1182 is electrically connected to the p-doped well region 116 via the first contact C1, which is positioned at the first side 1021. A trench gate structure segment 120 is illustrated in FIG. 3B with its gate electrode 1201 extending vertically through the intermediate dielectric 112. A contact opening 122 in the intermediate dielectric 112 allows for the electrical connection of the gate electrode 1201 to the gate interconnection line 108, ensuring proper functionality of the trench gate structure segment 120. The intermediate dielectric 112 acts as an insulating layer, separating the second contact C2 from the underlying gate electrode 1201.

FIG. 3C illustrates a cross-sectional view along line C-C′ of FIG. 3A providing a detailed depiction of the structural configuration, highlighting the integration of the gate interconnection line, intermediate dielectric, and doped regions.

FIG. 3C also shows the n-doped interconnection region 118, labeled as 1182 having a width w11 in this view, situated between the intermediate dielectric 112 and the p-doped well region 116. Similar to FIG. 3B, the n-doped interconnection region 1182 is electrically connected to the p-doped well region 116 via the first contact C1, which is positioned at the first side 1021. The trench gate structure segment 120 of FIG. 3B is omitted in FIG. 3C since the n-doped interconnection region 1182 extends along the first lateral direction x1 and ends below the second contact C2. The n-doped interconnection region 1182 is electrically connected to the p-doped well region 116 via the second contact C2 in a contact opening of the intermediate dielectric 112.

FIG. 3D is a more detailed illustration of the top view of FIG. 3A in the area of the lines B-B′ and A-A′.

The width of the second sub-region 1182 of the n-doped interconnection region 118 alternates along the second lateral direction x2 between the first width w11 and the second width w12. The second width w12 is smaller than the first width w11. This alternating width configuration is crucial for the layout and electrical characteristics of the semiconductor device by ensuring that i) the gate electrode 1201 in the trench gate structure segment 120 is electrically connected to the gate interconnection line 108 as is illustrated in FIG. 3B, and ii) the n-doped interconnection region 118 is electrically connected to the p-doped well region 116 via the second contact C2 as is illustrated in FIG. 3C.

Although specific examples have been illustrated and described herein, it will be appreciated by those of ordinary skill in the art that a variety of alternate and/or equivalent implementations may be substituted for the specific examples shown and described without departing from the scope of the disclosed subject matter. This application is intended to cover any adaptations or variations of the specific examples discussed herein. Therefore, it is intended that the disclosed subject matter be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosed subject matter and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosed subject matter, as well as specific examples thereof, are intended to encompass equivalents thereof.

1. A semiconductor device, comprising:
a silicon carbide (SiC) semiconductor body including a transistor cell array at a first side of the SiC semiconductor body;
a gate interconnection line, wherein at least a portion of the gate interconnection line is arranged between an edge of the SiC semiconductor body and the transistor cell array;
an intermediate dielectric arranged between the gate interconnection line and the SiC semiconductor body;
a p-doped well region; and
an n-doped interconnection region arranged between the gate interconnection line and the p-doped well region, wherein the n-doped interconnection region and the p-doped well region are electrically connected together by a first contact arranged at the first side between the gate interconnection line and the edge of the SiC semiconductor body, and the n-doped interconnection region and the p-doped well region are further electrically connected together by a second contact at the first side, the gate interconnection line being arranged between the first contact and the second contact.

2. The semiconductor device of claim 1, wherein a sheet resistance of the n-doped interconnection region is 20% or less than the sheet resistance of the p-doped well region.

3. The semiconductor device of claim 2, wherein the sheet resistance of the n-doped interconnection region is in a range from 300 Ohm/square to 900 Ohm/square.

4. The semiconductor device of claim 1, wherein a thickness of the first contact along a vertical direction is smaller than a thickness of the gate interconnection line.

5. The semiconductor device of claim 1, wherein a width of the first contact is in a range from 4% to 30% of a width of the gate interconnection line.

6. The semiconductor device of claim 4, wherein the thickness of the first contact is smaller than a thickness of the intermediate dielectric.

7. The semiconductor device of claim 1, wherein the p-doped well region turns into a p-doped edge termination region of an edge termination structure, the p-doped edge termination region having a higher sheet resistance than the p-doped well region.

8. The semiconductor device of claim 7, wherein a vertical extent of the p-doped edge termination region is larger than a vertical extent of the n-doped interconnection region, and a vertical extent of the p-doped well region is larger than the vertical extent of the p-doped edge termination region.

9. The semiconductor device of claim 8, wherein a maximum doping concentration in the p-doped well region is in a range from 10¹⁸ cm⁻³ to 10¹⁹ cm⁻³, and the vertical extent of the p-doped well region is in a range from 0.5 μm to 1.0 μm.

10. The semiconductor device of claim 1, wherein a source region in the transistor cell array and the n-doped interconnection region have a matching vertical concentration profile of n-type dopants.

11. The semiconductor device of claim 1, wherein the transistor cell array includes a plurality of stripe-shaped transistor cells (TC) extending in parallel along a first lateral direction, wherein the n-doped interconnection region includes a first sub-region extending in parallel to a first edge of the SiC semiconductor body along the first lateral direction, and the n-doped interconnection region further includes a second sub-region extending in parallel to a second edge of the SiC semiconductor body along a second lateral direction.

12. The semiconductor device of claim 11, wherein a width of the first sub-region along the second lateral direction is smaller than three times a width of the gate interconnection line over the first sub-region.

13. The semiconductor device of claim 11, wherein a width of the second sub-region alternates, along the second lateral direction, between a first width and a second width, the second width being smaller than the first width.

14. The semiconductor device of claim 13, wherein the second width is in a range from 10% to 30% of the first width.

15. The semiconductor device of claim 13, wherein a trench gate structure segment is laterally confined, along the second lateral direction, by neighboring segments of the second sub-region having the first width.

16. The semiconductor device of claim 15, wherein the trench gate structure segment adjoins, along the first lateral direction, a segment of the second sub-region having the second width.

17. The semiconductor device of claim 16, wherein a gate electrode of the trench gate structure segment is electrically connected to the gate interconnection line over the trench gate structure segment via a contact opening in the intermediate dielectric.

18. A method of manufacturing a semiconductor device, the method comprising:
forming a transistor cell array at a first side of a silicon carbide (SiC) semiconductor body;
forming an intermediate dielectric on the SiC semiconductor body;
forming a gate interconnection line on the intermediate dielectric, wherein at least a portion of the gate interconnection line is formed between an edge of the SiC semiconductor body and the transistor cell array;
forming a p-doped well region; and
forming an n-doped interconnection region arranged between the gate interconnection line and the p-doped well region, wherein the n-doped interconnection region and the p-doped well region are electrically connected together by a first contact arranged at the first side between the gate interconnection line and the edge of the SiC semiconductor body, and the n-doped interconnection region and the p-doped well region are further electrically connected together by a second contact at the first side, the gate interconnection line being arranged between the first contact and the second contact.

19. The method of claim 18, comprising:
concurrently forming an n-doped source region in the transistor cell array and the n-doped interconnection region by introducing n-type dopants into the SiC semiconductor body.

20. A semiconductor device, comprising:
a silicon carbide (SiC) semiconductor body including a transistor cell array at a first side of the SiC semiconductor body;
a gate interconnection line;
an intermediate dielectric;
a p-doped well region; and
an n-doped interconnection region, wherein the n-doped interconnection region and the p-doped well region are electrically connected together by a first contact arranged at the first side between the gate interconnection line and an edge of the SiC semiconductor body, and the n-doped interconnection region and the p-doped well region are further electrically connected together by a second contact at the first side.
